(19) United States
(12) Patent Application Publication
(10) Pub. No.: US 2026/0076215 A1
(43) Pub. Date: Mar. 12, 2026

(54) SEMICONDUCTOR PACKAGE AND PACKAGE MODULE INCLUDING THE SAME

(71) Applicant: Samsung Electronics Co., Ltd., Suwon-si (KR)

(72) Inventors: NARAE SHIN, Suwon-si (KR); SOYOUNG LIM, Suwon-si (KR)

(21) Appl. No.: 19/082,872

(22) Filed: Mar. 18, 2025

(30) Foreign Application Priority Data
Sep. 9, 2024 (KR) 10-2024-0122662
Oct. 30, 2024 (KR) 10-2024-0150843

(51) Int. Cl. H01L 23/495; H01L 23/00

(52) U.S. Cl. CPC H10W 70/421; H10W 70/453; H10W 72/248; H10W 74/15; H10W 90/724; H10W 90/734

(57) ABSTRACT

A semiconductor package includes a film substrate that includes a chip region, a first edge region, and a second edge region. The semiconductor package includes a semiconductor chip on the chip region, where the semiconductor chip includes first conductive bumps adjacent to the first edge region and second conductive bumps adjacent to the second edge region. The semiconductor package includes first pads and second pads on the first edge region, and first lines that electrically connect ones of the first pads to ones of the first conductive bumps. The second pads are dummy pads. A first set of the second pads and a second set of the second pads are spaced apart from each other in the second direction with the first pads therebetween. The first set of second pads includes ten or more consecutive second pads with no first pads therebetween.

### CROSS-REFERENCE TO RELATED APPLICATIONS

This application claims priority under 35 U.S.C § 119 to Korean Patent Applications No. 10-2024-0122662 filed on Sep. 9, 2024 and No. 10-2024-0150843 filed on Oct. 30, 2024 in the Korean Intellectual Property Office, the disclosures of which are hereby incorporated by reference in their entirety.

### TECHNICAL FIELD

The present disclosure relates to a semiconductor package and a package module including the same.

### BACKGROUND

A chip-on-film (COF) package technique has been developed to use a flexible film substrate based on a recent trend of smaller, thinner, and lighter electronic products. According to the COF package technique, a semiconductor chip may be directly flip-chip bonded to a film substrate and coupled through a short lead to an external circuit. The COF package may be applied to portable terminal devices such as a cellular phone and a personal digital assistant (PDA), laptop computers, or display panels.

### SUMMARY

Some embodiments of the present disclosure provide a semiconductor package with improved reliability.

Some embodiments of the present disclosure provide a package module with improved reliability.

An object of the present disclosure is not limited to the mentioned above, and other objects which have not been mentioned above will be clearly understood to those skilled in the art from the following description.

According to some embodiments of the present disclosure, a semiconductor package may comprise: a film substrate that includes a chip region, a first edge region, and a second edge region, where the first edge region and the second edge region are spaced apart from each other in a first direction with the chip region therebetween. The semiconductor package includes a semiconductor chip on the chip region, where the semiconductor chip includes first conductive bumps adjacent to the first edge region and second conductive bumps adjacent to the second edge region. The semiconductor package includes first pads and second pads on the first edge region and first lines that electrically connect ones of the first pads to ones of the first conductive bumps. The first pads, the first conductive bumps, and the second conductive bumps are spaced apart from each other in a second direction orthogonal to the first direction. The second pads are dummy pads that are electrically insulated from the first conductive bumps and the second conductive bumps. A first set of the second pads and a second set of the second pads are spaced apart from each other in the second direction with the first pads therebetween. The first set of second pads includes ten or more consecutive second pads with no first pads therebetween.

According to some embodiments of the present disclosure, a semiconductor package may comprise: a film substrate that includes a chip region, a first edge region, and a second edge region, where the first edge region and the second edge region are spaced apart from each other in a first direction with the chip region therebetween. The semiconductor package includes a semiconductor chip on the chip region, where the semiconductor chip includes first conductive bumps adjacent to the first edge region and second conductive bumps adjacent to the second edge region. The semiconductor package includes first pads and dummy pads on the first edge region, where the dummy pads are electrically insulated from first conductive bumps and the second conductive bumps. The semiconductor package includes second pads on the second edge region. The semiconductor package includes first lines that are electrically connected to ones of the first pads. The semiconductor package includes second lines that are electrically connected to ones of the second pads, where the first pads at least partially overlap the semiconductor chip in a first direction that is parallel to an upper surface of the film substrate.

According to some embodiments of the present disclosure, a semiconductor package module may comprise: a circuit substrate, a display panel spaced apart from the circuit substrate, and a semiconductor package between the circuit substrate and the display panel. The semiconductor package includes: a film substrate that includes a chip region, a first edge region, and a second edge region, where the chip region is between the first edge region and the second edge region, where the first edge region is adjacent to the circuit substrate, and where the second edge region is adjacent to the display panel a semiconductor chip on the chip region. The semiconductor package includes first pads and second pads on the first edge region, third pads on the second edge region, first lines between the film substrate and the semiconductor chip, where the first lines are electrically connected to ones of the first pads, second lines between the film substrate and the semiconductor chip, where the second lines are electrically connected to ones of the third pads, first conductive bumps between the semiconductor chip and the first lines, and second conductive bumps between the semiconductor chip and the second lines. The second pads are farther than the first pads from a center of the film substrate in a first direction, at least two of the first pads are spaced part from each other in the first direction by a first pitch, and the first pitch is in a range of about 120 μm to about 300 μm.

### BRIEF DESCRIPTION OF DRAWINGS

FIG. 1 illustrates a plan view showing a semiconductor package according to some embodiments of the present disclosure.

FIG. 2 illustrates a cross-sectional view taken along line A-A′ of FIG. 1.

FIG. 3 illustrates an enlarged view showing section CU1 of FIG. 1.

FIG. 4 illustrates a plan view showing a semiconductor package according to some embodiments of the present disclosure.

FIG. 5 illustrates an enlarged view showing section CU2 of FIG. 4.

FIG. 6 illustrates a plan view showing a semiconductor package according to some embodiments of the present disclosure.

FIG. 7 illustrates a plan view showing a semiconductor package module according to some embodiments of the present disclosure.

### DETAILED DESCRIPTION OF EMBODIMENTS

The following will now describe in detail some embodiments of the present disclosure with reference to the accompanying drawings. To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

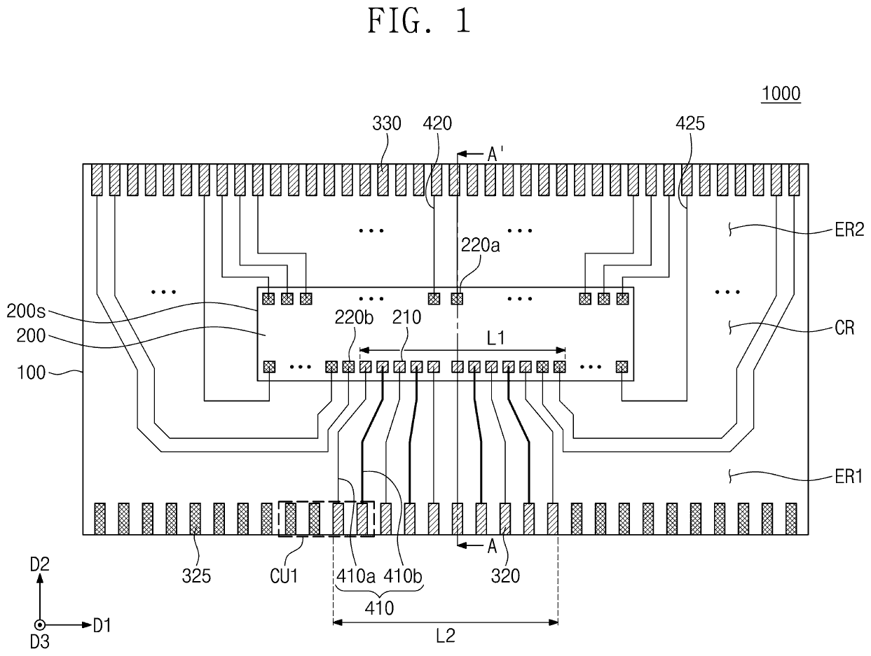

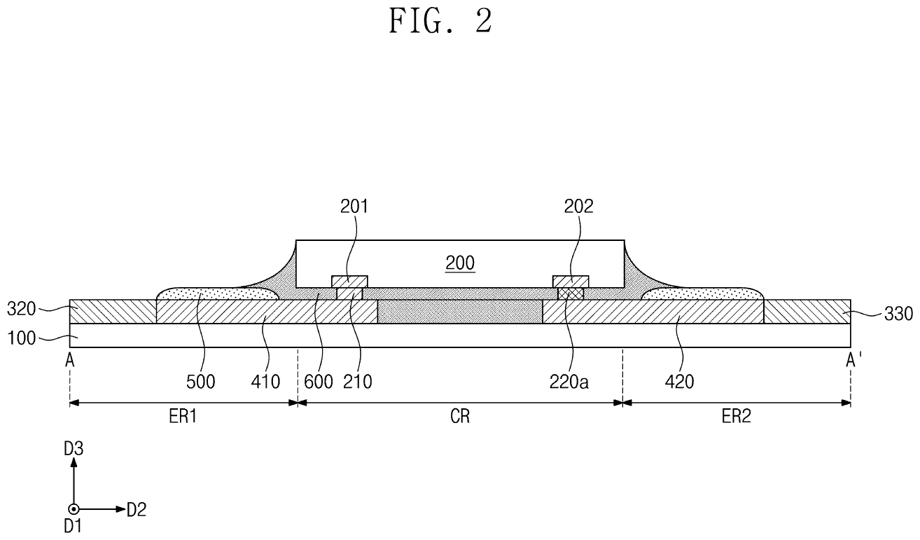

FIG. 1 illustrates a plan view showing a semiconductor package according to some embodiments of the present disclosure. FIG. 2 illustrates a cross-sectional view taken along line A-A′ of FIG. 1.

Referring to FIGS. 1 and 2, a semiconductor package 1000 according to some embodiments of the present disclosure may include a film substrate 100, a semiconductor chip 200, first pads 320, second pads 325, and third pads 330.

In this description, a first direction D1 may be defined to refer to a direction parallel to a top surface of the film substrate 100. A second direction D2 may be defined to refer to a direction parallel to the top surface of the film substrate 100 and orthogonal to the first direction D1. A third direction D3 may be defined to refer to a direction perpendicular to the top surface of the film substrate 100.

The film substrate 100 may have a plate shape that extends along a plane elongated in the first direction D1 and the second direction D2. The film substrate 100 may include a polymeric material. For example, the film substrate 100 may include polyimide. The film substrate 100 may be a flexible soft substrate. The film substrate 100 may be bendable.

The film substrate 100 may include a chip region CR on which the semiconductor chip 200 is disposed, and may also include a first edge region ER1 and a second edge region ER2 which surround or extend around the chip region CR. The first edge region ER1 and the second edge region ER2 may be spaced apart in the second direction D2 from each other across the chip region CR (e.g., the chip region CR is between the first edge region ER1 and the second edge region ER2).

The semiconductor chip 200 may be disposed on the chip region CR of the film substrate 100. The semiconductor chip 200 may have a tetragonal shape when viewed in plan. First chip pads 201 and second chip pads 202 may be disposed on a bottom surface of the semiconductor chip 200. The semiconductor chip 200 may have opposite lateral surfaces 200s that face each other in the first direction D1.

The semiconductor chip 200 may be a display driver IC that drives a display panel. The semiconductor chip 200 may generate image signals by using data signals transferred from a timing controller, and may output the image signals to the display panel. In some embodiments, the semiconductor chip 200 may be a timing controller connected to the display driver IC.

The semiconductor chip 200 may include first bumps 210, second bumps 220a, and third bumps 220b on the bottom surface thereof. The first bumps 210 and the third bumps 220b may be in contact with the first chip pads 201. The second bumps 220a may be in contact with the second chip pads 202. It should be understood that “bumps” may refer to electrically conductive bumps.

The first bumps 210 and the third bumps 220b may be disposed adjacent to the first edge region ER1. The third bumps 220b may be positioned farther than the first bumps 210 from a center of the semiconductor chip 200. The second bumps 220a may be disposed adjacent to the second edge region ER2. A length over which the second bumps 220a are disposed may be greater than a length over which the first bumps 210 are disposed. A width L1 of an area where the first bumps 210 are disposed (e.g., a distance between outermost ones of the plurality of first bumps 210) may be about 30% to about 50% of a length of the semiconductor chip 200 in the first direction D1. The first, second, and third bumps 210, 220a, and 220b may include a conductive material. For example, the first, second, and third bumps 210, 220a, and 220b may include may include copper (Cu).

The first pads 320 and the second pads 325 may be disposed on the first edge region ER1. The first pads 320 may be input pads configured to conduct input signals to the semiconductor chip 200. The second pads 325 may be dummy pads that are electrically insulated from the first, second, and third bumps 210, 220a, and/or 220b. The first pads 320 may be connected to first lines 410 (e.g., conductive wires), which will be discussed below. In some embodiments, the second pads 325 may not be connected to first lines 410, which will be discussed below. The second pads 325 may be disposed spaced apart from each other in the first direction D1 across the first pads 320 (e.g., the first pads 320 may be between a first set of the second pads 325 and a second set of the pads 325 that are spaced apart from each other in the first direction D1). The first pads 320 may be disposed closer than the second pads 325 to a center of the film substrate 100. The second pads 325 may be disposed farther than the first pad 320 from the center of the film substrate 100. For example, the second pads 325 may be adjacent to opposite side portions of the film substrate 100. In a plan view, the first pads 320 may be positioned inside or between the second pads 325.

Outermost ones of the first pads 320 may be disposed within a width between the opposite lateral surfaces 200s of the semiconductor chip 200 that face each other in the first direction D1 (e.g., each of the first pads 320 at least partially overlaps the semiconductor chip 200 in the second direction D2). One or more of the second pads 325 may be disposed outside the opposite lateral surfaces 200s of the semiconductor chip 200 (e.g., one or more of the second pads 325 are free from overlap with the semiconductor chip 200 in the second direction D2). The second pads 325 may be disposed farther than the first bumps 210 from the center of the film substrate 100. A width of an area where the first pads 320 may be (e.g., a distance between outermost ones of the plurality of first pads 320 in the first direction D1) is about 30% to about 50% of a length of one surface of the film substrate 100 (e.g., a length of the film substrate 100 in the first direction D1). The number of the first pads 320 and the number of the second pads 325 are not limited to that shown in FIG. 1, and may be provided in greater quantity. For example, the number of the second pads 325 (e.g., a total number or a number of each set on either side of the first pads 320) may be ten or more that continuously extend on the film substrate 100 (e.g., ten or more consecutive second pads 325 with no first pads 320 intervening therebetween).

The third pads 330 may be disposed on the second edge region ER2. The third pads 330 may be output pads configured to conduct output signals from the semiconductor chip 200. A length over which the third pads 330 are disposed in the first direction D1 on the film substrate 100 may be greater than a length over which the first pads 320 are disposed in the first direction D1 on the film substrate 100. A spacing distance in the first direction D1 between adjacent ones of the third pads 330 may be less than a spacing distance in the first direction D1 between adjacent ones of the first pads 320. The number of the third pads 330 is not limited to that shown, and may be provided in greater quantity.

The first, second, and third pads 320, 325, and 330 may include a conductive material. For example, the first, second, and third pads 320, 325, and 330 may include copper (Cu).

First lines 410 may be provided to connect the first pads 320 to the semiconductor chip 200. The first lines 410 may run across or extend along the first edge region ER1. For example, the first lines 410 may be disposed between the film substrate 100 and the semiconductor chip 200. The first lines 410 may be in corresponding contact with the first bumps 210 and the first pads 320. The number of the first lines 410 is not limited to that shown, and may be provided in greater quantity. Outermost ones of the first lines 410 may be disposed within a width between the opposite lateral surfaces 200s of the semiconductor chip 200 that face each other in the first direction D1 (e.g., each of the first lines 410 at least partially overlaps the semiconductor chip 200 in the second direction D2).

The first lines 410 may include first sub-lines 410a and second sub-lines 410b. The first sub-lines 410a may be signal lines, and may be pathways along which data and control signals are transmitted. The second sub-lines 410b may be ground lines configured to be connected to an electrical ground. A width of the second sub-line 410b may be greater than a width of the first sub-line 410a.

Second lines 420 and third lines 425 may be provided to connect the third pads 330 to the semiconductor chip 200. The second lines 420 may run across or extend along the second edge region ER2. The third lines 425 may continuously extend on the second edge region ER2, the chip region CR, and the first edge region ER1.

For example, the second lines 420 and the third lines 425 may be disposed between the film substrate 100 and the semiconductor chip 200. The second lines 420 may be in corresponding contact with the second bumps 220a and the third pads 330 (e.g., a first set of the third pads 330). The third lines 425 may be in corresponding contact with the third bumps 220b and the third pads 330 (e.g., a second set of the third pads 330). The number of the second lines 420 and the number of the third lines 425 are not limited to that shown, and may be provided in greater quantity.

As illustrated in FIG. 2, a line protection layer 500 may be disposed on the film substrate 100 to cover or at least partially overlap the first lines 410, the second lines 420, and the third lines 425. The line protection layer 500 may at least partially expose the first pads 320, the second pads 325, and the third pads 330. The line protection layer 500 may include a dielectric material. For example, the line protection layer 500 may include a solder resist material.

An underfill layer 600 may be disposed between the bottom surface of the semiconductor chip 200 and the top surface of the film substrate 100. For example, the underfill layer 600 may cover or at least partially overlap a lateral surface of the semiconductor chip 200, a portion of a top surface of the line protection layer 500, lateral surfaces of the first, second, and third bumps 210, 220a, and 220b, portions of top and lateral surfaces of the first, second, and third lines 410, 420, and 425, and a portion of the top surface of the film substrate 100. The underfill layer 600 may include a dielectric material. For example, the underfill layer 600 may include an epoxy-based polymer.

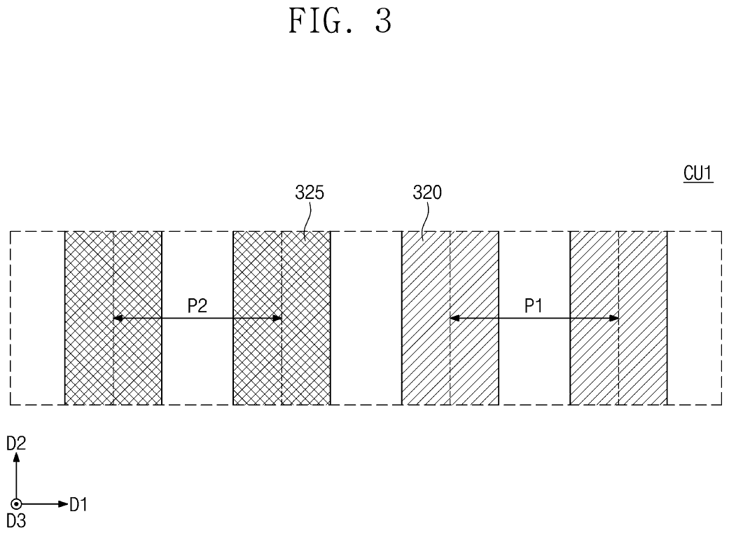

FIG. 3 illustrates an enlarged view showing section CU1 of FIG. 1. Omission will be made to avoid repetitive descriptions of the same features as those of FIGS. 1 and 2.

Referring to FIGS. 2 and 3, the first pads 320 may be spaced apart in the first direction D1 from each other at a first pitch P1. The second pads 325 may be spaced apart in the first direction D1 from each other at a second pitch P2.

The first pitch P1 and the second pitch P2 may be substantially the same. For example, the first pitch P1 and the second pitch P2 may range from about 120 μm to about 300 μm. For example, the first pitch P1 and the second pitch P2 may be about 200 μm.

On the film substrate 100, the second pads 325 may be provided with a substantially identical pitch as that of the first pads 320, and thus the film substrate 100 may be prevented or inhibited from being bent. In addition, the second pads 325 may cause components to have a uniform efficient of thermal expansion when the film substrate 100 is connected to a circuit substrate, which will be discussed below.

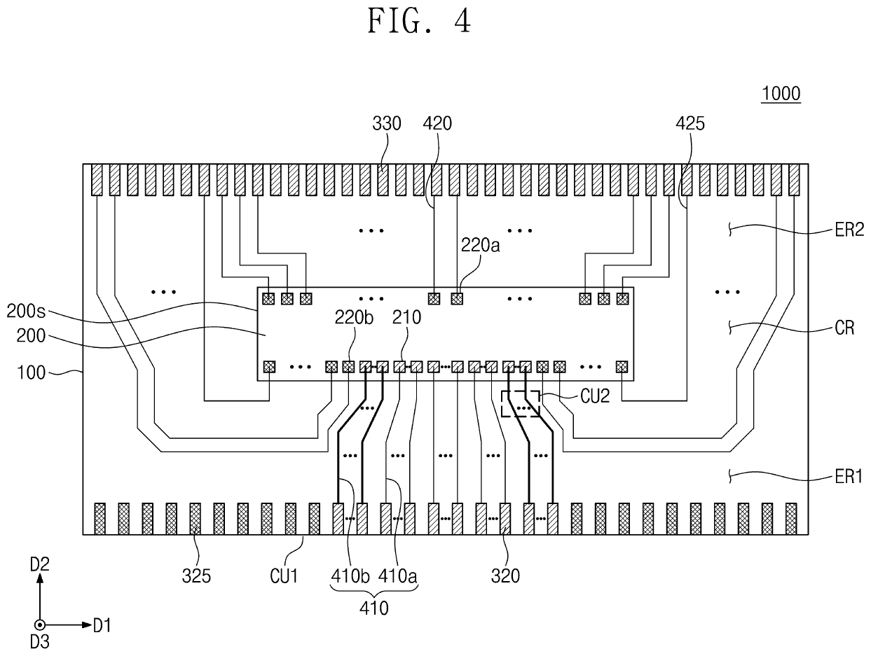

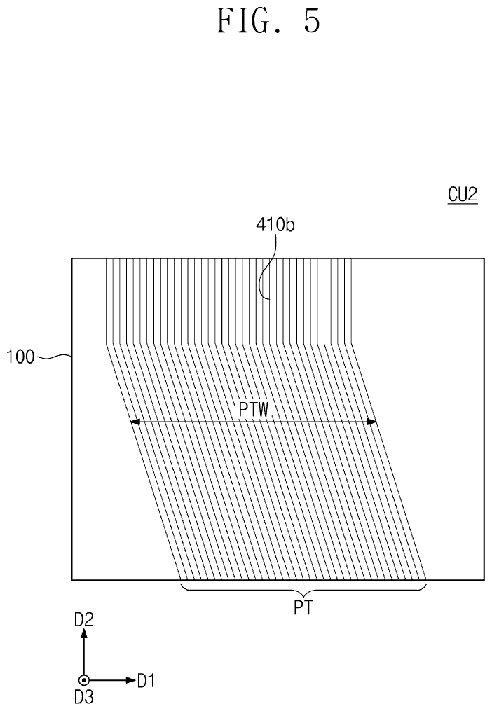

FIG. 4 illustrates a plan view showing a semiconductor package according to some embodiments of the present disclosure. FIG. 5 illustrates an enlarged view showing section CU2 of FIG. 4. Omission will be made to avoid repetitive descriptions of the same features as those of FIGS. 1 to 3.

Referring to FIGS. 4 and 5, the second sub-lines 410b may be positioned farther than the first sub-lines 410a from the center of the film substrate 100. For example, when viewed in plan, the first sub-lines 410a may be positioned inside or between the second sub-lines 410b.

The first sub-lines 410a and the second sub-lines 410b may be provided in greater quantity than that shown in FIG. 4, thereby constituting a pattern. For example, as shown in FIG. 5, a plurality of second sub-lines 410b may be provided on the film substrate 100, and the plurality of second sub-lines 410b may constitute one line pattern PT. A width PTW of the line pattern PT (e.g., a width between outermost ones of the second sub-lines 410b) may be in a range, for example, from about 500 μm to about 1,000 μm. The width PTW of the line pattern PT may be changed depending on the number of the first sub-lines 410a and the number of the second sub-lines 410b.

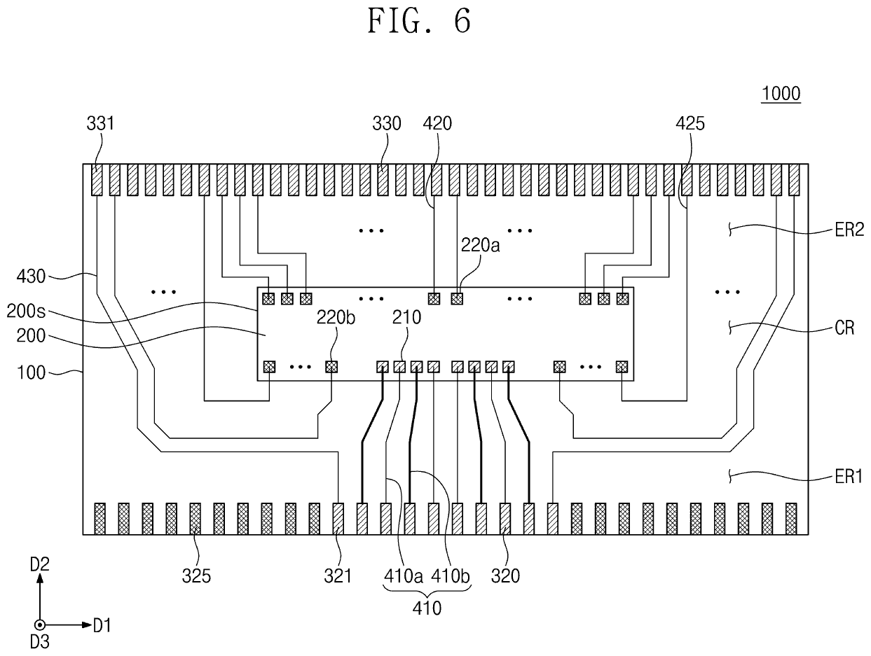

FIG. 6 illustrates a plan view showing a semiconductor package according to some embodiments of the present disclosure. Omission will be made to avoid repetitive descriptions of the same features as those of FIGS. 1 to 3.

Referring to FIG. 6, the semiconductor package 1000 according to some embodiments of the present disclosure may further include fourth lines 430, fourth pads 321, and fifth pads 331. The fourth pads 321 and the fifth pads 331 may be respectively provided on the first edge region ER1 and the second edge region ER2. The fourth pads 321 may be disposed farther than the first pads 320 from the center of the film substrate 100. The fifth pads 331 may be disposed farther than the third pads 330 from the center of the film substrate 100. The fourth lines 430 may connect the fourth pads 321 to the fifth pads 331. For examples, the fourth lines 430 may be wiring lines that directly connect the fourth pads 321 to the fifth pads 331, and may not connect the fourth lines 430 to the semiconductor chip 200. The fourth lines 430 may be, for example, bypass lines. When viewed in plan, the fourth lines 430 may be disposed further outward than the first, second, and third lines 410, 420, and 425. The number and arrangement of the fourth lines 430 are not limited to that shown, and may be combined and changed without restriction.

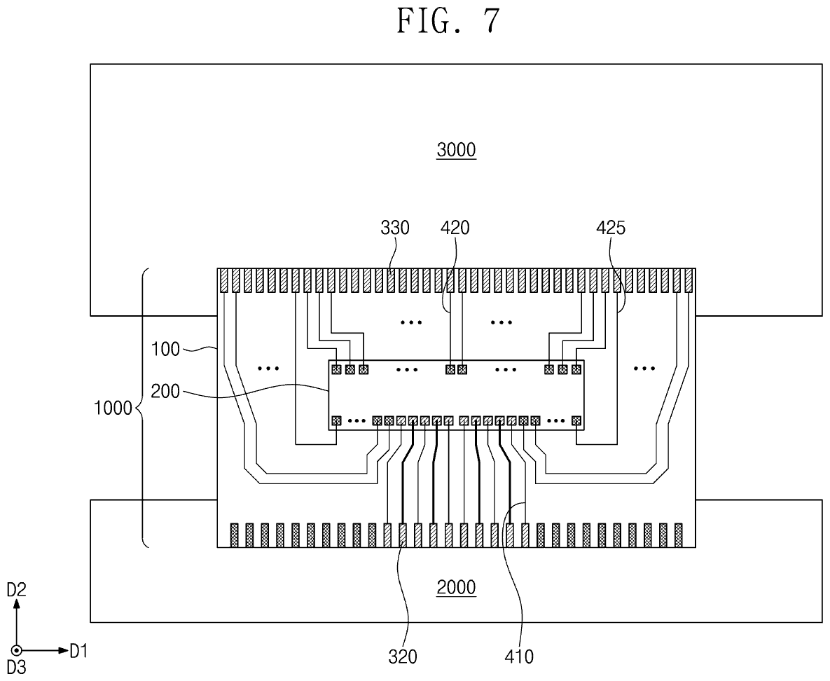

FIG. 7 illustrates a plan view showing a semiconductor package module according to some embodiments of the present disclosure.

Referring to FIG. 7, a semiconductor package module 1 according to some embodiments of the present disclosure may include a semiconductor package 1000, a circuit substrate 2000, and a display panel 3000.

Only the semiconductor package 1000 of FIG. 1 is illustrated as the semiconductor package 1000 of the semiconductor package module 1, but the semiconductor package 1000 may be replaced with other semiconductor packages according to some embodiments of the present disclosure. FIG. 7 depicts only one semiconductor package, but there may be no limitation on the number of the semiconductor package.

The circuit substrate 2000 may be disposed on a top surface of the film substrate 100 of the semiconductor package 1000. The circuit substrate 2000 may be adjacent to one side of the film substrate 100. The circuit substrate 2000 may be a printed circuit board (PCB) or a flexible printed circuit board (FPCB). An input connection section (not shown) may be interposed between and connect the first pads 320 and the circuit substrate 2000. The circuit substrate 2000 may be electrically connected to the semiconductor chip 200 through the first pads 320 and the first lines 410.

The display panel 3000 may be disposed on the top surface of the film substrate 100 of the semiconductor package 1000. The display panel 3000 may be adjacent to another side of the film substrate 100. An output connection section (not shown) may be interposed between and connect the third pads 330 and the display panel 3000. The display panel 3000 may be electrically connected to the semiconductor chip 200 through the third pads 330, the second lines 420, and the third lines 425.

The semiconductor chip 200 may be supplied with signals from the circuit substrate 2000 through the first pads 320 and the first lines 410. The semiconductor chip 200 may be a driving integrated circuit (e.g., a gate driving integrated circuit and/or a data driving integrated circuit), and may generate driving signals (e.g., gate driving signals and/or data driving signals).

The driving signals generated from the semiconductor chip 200 may be supplied through the third pads 330, the second lines 420, and the third lines 425 to a gate line and/or a data line of the display panel 3000. Therefore, the display panel 3000 may operate.

A semiconductor package according to some embodiments of the present disclosure may include a film substrate, a semiconductor chip disposed on the film substrate, pads, and lines that connect the semiconductor chip to the pads. The pads may be provided between dummy pads. For example, the pads may be disposed within a width between opposite lateral surfaces of the semiconductor chip, and a pitch between the pads may range from about 120 μm to about 300 μm. Thus, there may be a reduction in length of lines through which the pads are connected to the semiconductor chip, and a plurality of lines may be provided to constitute a line pattern, there may be an increase in width of the line pattern. As a result, a resistance generated from the line may decrease to reduce heating of the semiconductor package, thereby improving heat radiation characteristics.

A semiconductor package according to some embodiments of the present disclosure may include a film substrate, a semiconductor chip disposed on the film substrate, pads, and lines that connect the semiconductor chip to the pads. The pads may be provided between dummy pads, and a pitch between the pads may range from about 120 μm to about 300 μm. Thus, there may be a reduction in length of lines through which the pads are connected to the semiconductor chip, and a plurality of lines may be provided to constitute a line pattern, there may be an increase in width of the line pattern. As a result, a resistance generated from the line may decrease to reduce heating of the semiconductor package, thereby improving heat radiation characteristics.

Although the present disclosure has been described in connection with some embodiments of the present disclosure illustrated in the accompanying drawings, it will be understood to those skilled in the art that various changes and modifications may be made without departing from features of the present disclosure. It will be apparent to those skilled in the art that various substitution, modifications, and changes may be thereto without departing from the scope of the present disclosure.

What is claimed is

1. A semiconductor package, comprising:
a film substrate that comprises a chip region, a first edge region, and a second edge region, wherein the first edge region and the second edge region are spaced apart from each other in a first direction with the chip region therebetween;
a semiconductor chip on the chip region, wherein the semiconductor chip comprises first conductive bumps adjacent to the first edge region and second conductive bumps adjacent to the second edge region;
first pads and second pads on the first edge region; and
first lines that electrically connect ones of the first pads to ones of the first conductive bumps,
wherein the first pads, the first conductive bumps, and the second conductive bumps are spaced apart from each other in a second direction orthogonal to the first direction,
wherein the second pads are dummy pads that are electrically insulated from the first conductive bumps and the second conductive bumps,
wherein a first set of the second pads and a second set of the second pads are spaced apart from each other in the second direction with the first pads therebetween, and
wherein the first set of second pads comprises ten or more consecutive second pads with no first pads therebetween.

2. The semiconductor package of claim 1, wherein the first lines at least partially overlap the semiconductor chip in the second direction.

3. The semiconductor package of claim 1, wherein one or more of the second pads are free from overlap with the semiconductor chip in the second direction.

4. The semiconductor package of claim 1, wherein at least two of the first pads are spaced apart from each other in the second direction by a first pitch, and
wherein the first pitch is in a range of about 120 μm to about 300 μm.

5. The semiconductor package of claim 4, wherein at least two of the second pads are spaced apart from each other in the second direction at a second pitch, and
wherein the second pitch is substantially the same as the first pitch.

6. The semiconductor package of claim 1, wherein a distance between outermost ones of the first pads in the second direction is about 30% to about 50% of a length of the film substrate in the second direction.

7. The semiconductor package of claim 1, wherein the semiconductor chip further comprises third conductive bumps adjacent to the first edge region, and
wherein the third conductive bumps are farther than the first conductive bumps from a center of the semiconductor chip in the second direction.

8. The semiconductor package of claim 7, further comprising:
third pads on the second edge region;
second lines that electrically connect a first set of the third pads to ones of the second conductive bumps; and
third lines that electrically connect a second set of the third pads to ones of the third conductive bumps.

9. The semiconductor package of claim 8, wherein the third lines extend on the second edge region, the chip region, and the first edge region.

10. The semiconductor package of claim 8, wherein:
the first pads are input pads configured to conduct input signals to the semiconductor chip, and
the third pads are output pads configured to conduct output signals from the semiconductor chip.

11. The semiconductor package of claim 8, further comprising:
fourth pads on the first edge region;
fifth pads on the second edge region; and
fourth lines that electrically connect the fourth pads to the fifth pads,
wherein the fourth pads are farther than the first pads from a center of the film substrate in the second direction, and
wherein the fifth pads are farther than the third pads from the center of the film substrate in the second direction.

12. The semiconductor package of claim 11, wherein, in plan view, the fourth lines are farther than the first lines, the second lines, and the third lines from the center of the film substrate in the second direction.

13. A semiconductor package, comprising:
a film substrate that comprises a chip region, a first edge region, and a second edge region, wherein the first edge region and the second edge region are spaced apart from each other in a first direction with the chip region therebetween;
a semiconductor chip on the chip region, wherein the semiconductor chip comprises first conductive bumps adjacent to the first edge region and second conductive bumps adjacent to the second edge region;
first pads and dummy pads on the first edge region, wherein the dummy pads are electrically insulated from first conductive bumps and the second conductive bumps;
second pads on the second edge region;
first lines that are electrically connected to ones of the first pads; and
second lines that are electrically connected to ones of the second pads,
wherein the first pads at least partially overlap the semiconductor chip in a first direction that is parallel to an upper surface of the film substrate.

14. The semiconductor package of claim 13, wherein the first pads are closer than the dummy pads to a center of the film substrate in the first direction.

15. The semiconductor package of claim 13, wherein a length in the first direction between outermost ones of the second pads is greater than a length in the first direction between outermost ones of the first pads.

16. The semiconductor package of claim 13, wherein a distance in the first direction between outermost ones of the first conductive bumps is about 30% to about 50% of a length in the first direction of the semiconductor chip.

17. A semiconductor package module, comprising:
a circuit substrate;
a display panel spaced apart from the circuit substrate; and
a semiconductor package between the circuit substrate and the display panel,
wherein the semiconductor package comprises:
a film substrate that comprises a chip region, a first edge region, and a second edge region, wherein the chip region is between the first edge region and the second edge region, wherein the first edge region is adjacent to the circuit substrate, and wherein the second edge region is adjacent to the display panel;
a semiconductor chip on the chip region;
first pads and second pads on the first edge region;
third pads on the second edge region;
first lines between the film substrate and the semiconductor chip, wherein the first lines are electrically connected to ones of the first pads;
second lines between the film substrate and the semiconductor chip, wherein the second lines are electrically connected to ones of the third pads;
first conductive bumps between the semiconductor chip and the first lines; and
second conductive bumps between the semiconductor chip and the second lines,
wherein the second pads are farther than the first pads from a center of the film substrate in a first direction,
wherein at least two of the first pads are spaced part from each other in the first direction a first pitch, and
wherein the first pitch is in a range of about 120 μm to about 300 μm.

18. The semiconductor package module of claim 17, wherein the first lines comprises first sub-lines and second sub-lines,
wherein the first sub-lines are signal lines configured to provide signals to the semiconductor chip, and
wherein the second sub-lines are ground lines configured to be connected to an electrical ground.

19. The semiconductor package module of claim 18,
wherein a width in the first direction between outermost ones of the second sub-lines is in a range of about 500 μm to about 1,000 μm.

20. The semiconductor package module of claim 17, wherein a distance in the first direction between adjacent ones of the third pads is less than a distance in the first direction between adjacent ones of the first pads.
